(19) United States
(12) Patent Application Publication
(10) Pub. No.: US 2025/0349502 A1
(43) Pub. Date: Nov. 13, 2025

(54) PICTURE MODE RESOLUTION ENHANCEMENT FOR E-BEAM DETECTOR

(71) Applicant: ASML NETHERLANDS B.V., Veldhoven (NL)

(72) Inventors: Yongxin WANG, San Ramon, CA (US); Weiming REN, San Jose, CA (US)

(73) Assignee: ASML NETHERLANDS B.V., Veldhoven (NL)

(21) Appl. No.: 18/859,922

(22) PCT Filed: Jul. 13, 2023
(86) PCT No.: PCT/EP2023/069552

§ 371 Date: Oct. 24, 2024

Related U.S. Application Data
(60) Provisional application No. 63/368,604, filed on Jul. 15, 2022.

(51) Int. Cl. H01J 37/244; H01J 37/22; H01J 37/26; H01J 37/28

(52) U.S. Cl. CPC H01J 37/244; H01J 37/222; H01J 37/263; H01J 37/265; H01J 37/28; H01J 2237/24495

(57) ABSTRACT

A charged particle detector includes a plurality of sensing elements, with each sensing element being further divided into sub-sensing elements. The sub-sensing elements may be individually addressed during high-resolution image acquisition in a picture mode, and may be grouped together during high speed detection in a beam mode. The arrangement allows a selectable tradeoff between speed and resolution without introducing significant parasitic parameters.

### CROSS-REFERENCE TO RELATED APPLICATIONS

This application claims priority of U.S. application 63/368,604 which was filed on Jul. 15, 2022 and which is incorporated herein in its entirety by reference.

### TECHNICAL FIELD

The description herein relates to detectors, and more particularly, to detectors that may be applicable to charged particle detection.

### BACKGROUND

Detectors may be used for sensing physically observable phenomena. For example, some charged particle beam tools, such as electron microscopes, comprise detectors that receive charged particles projected from a sample and that output detection signals. Detection signals may be used to reconstruct images of sample structures under inspection and may be used, for example, to reveal defects in the sample. Detection of defects in a sample is increasingly important in the manufacturing of semiconductor devices, which may include large numbers of densely packed, miniaturized integrated circuit (IC) components. Inspection systems may be provided for this purpose. For example, a charged particle (e.g., electron) beam microscope, such as a scanning electron microscope (SEM) or a transmission electron microscope (TEM), capable of resolution down to less than a nanometer, serves as a practical tool for inspecting IC components having a feature size that is sub-100 nanometers. Electron microscopes work by irradiating a sample with an electron beam, then detecting secondary or backscattered electrons (or other types of secondary particles) on a detector. The secondary particles may form one or more beam spots on the detector surface.

Some detectors include a pixelated array of multiple sensing elements. A pixelated array can be useful because it may allow a detector configuration to be adapted to the size and shape of beam spots formed on the detector. When multiple primary beams are used, with multiple secondary beams incident on the detector, a pixelated array may be segregated into different regions of the detector associated with different beam spots. Each region may form its own group of sensing elements that are used to detect individual beam spots.

To form detection groups for the different beam spots, a typical process includes two steps. First, a picture of the detector surface is acquired. In a so-called “picture mode,” output of each of the sensing elements of the pixelated array may be read, and an image that represents a projection pattern of secondary beam spots on the detector surface may be formed. That is, an image of the entire detector surface is generated. Based on this image, a border of each beam spot may be estimated, and a group of sensing elements may be chosen such that a boundary of the group approximates the border of the beam spot. This chosen group of sensing elements may be used later to detect the beam spot during a “beam mode.”

### SUMMARY

Embodiments of the present disclosure provide systems and methods for charged particle detection.

Some embodiments comprise a charged particle detector configured to operate in a picture mode or a beam mode. The charged particle detector may comprise a substrate comprising a first plurality of sub-sensing elements configured to convert a charged particle landing event into an electrical signal. Each of the sub-sensing elements of the first plurality of sub-sensing elements may be coupled to a switch on a first side of the sub-sensing element, and may be coupled to a first sensing element node of a first sensing element on a second side of the sub-sensing element. Each of the first plurality of sub-sensing elements may be configured to generate a picture mode sub-pixel signal when the charged particle detector operates in the picture mode, in which each picture mode sub-pixel signal may be separately accessible to a signal processing circuit of the charged particle detector in the picture mode.

The first plurality of sub-sensing elements may be further configured to generate a first beam mode sensing element signal when the charged particle detector operates in the beam mode. The switches that are coupled to each of the sub-sensing elements in the first plurality of sub-sensing elements may be closed in the beam mode, so that the first beam mode sensing element signal is accessible to the signal processing circuit of the charged particle detector in the beam mode.

Some embodiments comprise a non-transitory computer-readable medium storing a set of instructions that are executable by at least one processor of a charged particle beam apparatus to cause the apparatus to perform a method. The method may comprise addressing a first sensing element of a plurality of sensing elements of a charged particle beam detector by connecting the first sensing element to a signal readout path of the charged particle beam apparatus. The first sensing element may comprise a first plurality of sub-sensing elements. Each sub-sensing element may be configured to convert a charged particle landing event into an electrical signal. Each of the sub-sensing elements of the first plurality of sub-sensing elements may be coupled to a switch on a first side of the sub-sensing element and may be coupled to a first sensing element node of the first sensing element on a second side of the sub-sensing element.

The method may further comprise, while the first sensing element is being addressed, individually addressing each sub-sensing element of first sensing element by successively toggling each switch coupled to each sub-sensing element on and off one at a time to individually connect each sub-sensing element of the first sensing element to the signal readout path. The method may further comprise performing an adjustment to the charged particle beam apparatus based on a signal obtained on the signal readout path from the first sensing element.

### BRIEF DESCRIPTION OF DRAWINGS

FIG. 1 is a diagram illustrating an exemplary charged-particle beam inspection system, consistent with embodiments of the present disclosure.

FIG. 2 is a diagram illustrating an exemplary multi-beam beam tool, consistent with embodiments of the present disclosure that can be a part of the exemplary charged-particle beam inspection system of FIG. 1.

FIGS. 3A-3B are representations of a charged particle detector, consistent with embodiments of the present disclosure.

FIG. 4A is a representation of a charged particle detector surface, according to a comparative embodiment.

FIG. 4B is a representation of a beam mode operation on the charged particle detector surface of FIG. 4A, according to a comparative embodiment.

FIG. 4C is a representation of a detector chip circuit design, according to a comparative embodiment.

FIG. 5A illustrates a charged particle detector surface, consistent with embodiments of the present disclosure.

FIG. 5B illustrates a beam mode operation on the charged particle detector surface of FIG. 5A, consistent with embodiments of the present disclosure.

FIG. 5C illustrates a detector chip circuit design, consistent with embodiments of the present disclosure.

FIGS. 6A-6C illustrate examples of a detector chip circuit design, consistent with embodiments of the present disclosure.

FIG. 7 illustrates a switch configuration for a sensing element circuit, consistent with embodiments of the present disclosure.

FIGS. 8A-8B illustrate switching elements in a detector chip circuit design, consistent with embodiments of the present disclosure.

FIG. 9 illustrates exemplary grouping arrangements of sub-sensing elements in a charged particle detector surface, consistent with embodiments of the present disclosure.

FIG. 10 is a flowchart of an exemplary method of generating a charged-particle detection signal, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing charged-particle beams (e.g., electron beams), the disclosure is not so limited. Other types of charged particle beams may be similarly applied. Furthermore, other imaging systems may be used, such as optical imaging, photodetection, x-ray detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). One example of a SCPM may be a scanning electron microscope (SEM). A SCPM can be used to image these extremely small structures, in effect, taking a “picture” of the structures of the wafer. The image can be used to determine if the structure was formed properly and at the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line, zig-zag, or serpentine manner), forming a primary beam spot at each location on the wafer. The detector may receive exiting electrons coming from a region under electron-beam projection (the primary beam spot), which may form a secondary beam spot on the detector surface. The detector may receive and record exiting electrons from each secondary beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) may, for example, take multiple “sub-pictures” of the wafer in parallel, where these sub-pictures can be inspected individually or collectively when these sub-pictures are stitched together. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Exiting electrons received by the detector of the SEM may cause the detector to generate electrical signals (e.g., current, charge, or voltage signals) commensurate with the energy of the exiting electrons and the intensity of the electron beam. For example, the amplitudes of the electrical signals may be commensurate with the intensity of the secondary beam spot formed on the detector by exiting electrons. The detector may output the electrical signals to an image processor, and the image processor may process the electrical signals to form the image of structures of the wafer. A multi-beam SEM system uses multiple electron beams for inspection, and a detector of the multi-beam SEM system may have multiple sections to receive them. Each section may have multiple sensing elements and may be used to form a “picture” of a sub-region of the wafer. The “picture” generated based on signals from each section of the detector may be merged, e.g., by a software program, to form a complete picture of the inspected wafer.

It may be desirable to provide a detector architecture that can be optimized for different operating modes. For instance, it may be desirable to optimize a detector for enhanced signal processing speed during one mode, whereas it may be preferable to optimize the detector for greater resolution in another operating mode.

For instance, there may be a first mode called a “picture mode,” which is used to associate a part of the detector surface with a particular beam spot. A detector may include a pixelated array of many small sensing elements. These sensing elements can be connected to each other in groups by a switch network to form combined signals when detecting an electron beam spot. However, when the sensing elements are grouped together, it is not possible to know exactly which sensing element any portion of the signal is coming from. So, each connected group can include only those elements that are expected to receive the same beam spot. Picture mode is a process used to determine the shape and location of each beam spot on the detector surface, in order to know which sensing elements should be grouped with each other during a normal detection process (called “beam mode”). During picture mode, high resolution is more important than processing speed.

In picture mode, the output of each of the sensing elements of the pixelated array may be read individually to determine every location on the detector surface that is receiving part of a beam spot. An image that represents a fine grain projection pattern of secondary beam spots on the detector surface may be formed (e.g., a secondary electron beam projection image). That is, fine grained image of the entire detector surface is generated. Based on this image, a border of each beam spot may be determined, and a group of sensing elements may be chosen such that the boundary of the group approximates the border of the beam spot, so that electrons of the beam land on the sensing elements of the group. This chosen group of sensing elements may be used later to detect the beam spot during beam mode. A picture mode resolution may refer to the minimum size of a sensing element when operating in picture mode.

In a “beam mode” during, e.g., an inspection process, sensing elements located within the determined boundary may be grouped together, and their outputs may be merged with each other to acquire intensity of the one secondary beam spot associated with the boundary. Thus, the picture mode may be useful for determining a boundary within which a desired grouping of sensing elements may be used during an inspection process in the beam mode. The switch matrix for interconnecting the sensing elements may include circuitry such as switches, wiring paths, and logical components between the sensing elements and readout circuitry of the detector. During beam mode, processing speed may be more important than high resolution. Due to “parasitic” effects, processing speed can be degraded by the amount of circuit components that are electrically connected to the system during detection, and well as the way they are connected. The more sensing elements, switches, etc. that are connected to a group during detection, the worse the parasitic effects become.

Like picture mode resolution, a beam mode resolution may refer to the minimum size of a sensing element when operating in beam mode. In conventional systems, the minimum size of a sensing element is fixed, and so it is the same in both picture and beam mode. Thus the picture mode resolution and beam mode resolution may be equal in conventional systems. However, it may be desirable to select a tradeoff among detector parameters, such as lower speed in exchange for higher resolution and vice versa, depending on which mode the detector is operating in.

Embodiments of the present disclosure provide a way to achieve this. Each sensing element is structured so that it can break itself into a smaller array of sub-sensing elements during picture mode for higher resolution, but it can operate as a single sensing element during beam mode for better processing speed. The design of this sensing element is such that circuit components for each sub-sensing element add little or no parasitic effects when operating as one large sensing element in beam mode. Therefore, high processing speed during beam mode is maintained.

Relative dimensions of components in drawings may be exaggerated for clarity. Within the following description of drawings, the same or like reference numbers refer to the same or like components or entities, and only the differences with respect to the individual embodiments are described.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

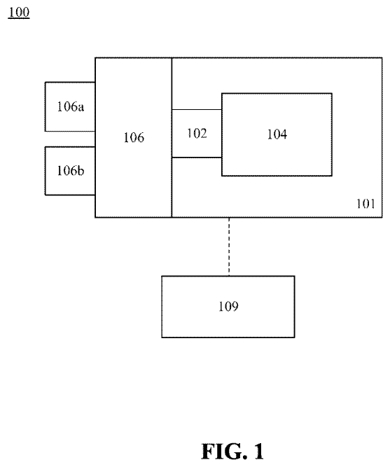

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafers from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

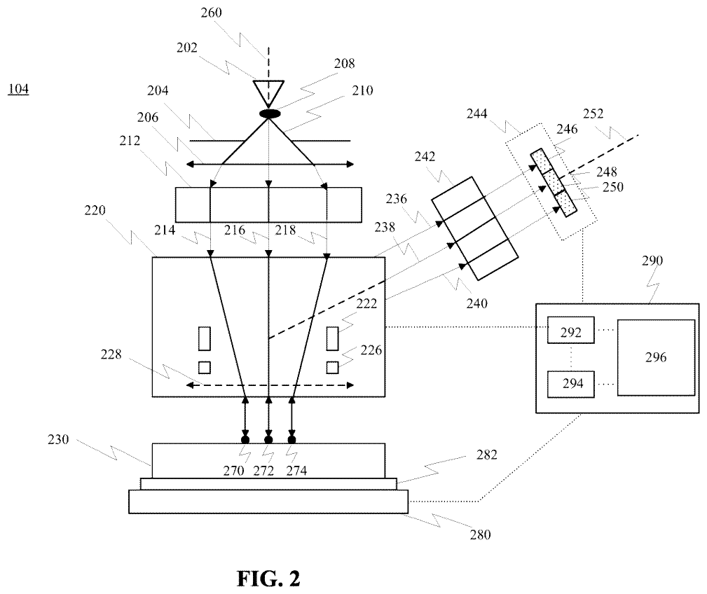

FIG. 2 illustrates an exemplary multi-beam tool 104 (also referred to herein as apparatus 104) and an image processing system 290 that may be configured for use in EBI system 100 (FIG. 1), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 2, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies≤50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct a scanning charged particle microscope (SCPM) image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire SCPM images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 2). The quantity of BSEs and SEs may be more or fewer than (or even the same as) the injected electrons of primary charged-particle beam 210.

The images generated by beam tool 104 may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, beam tool 104 may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

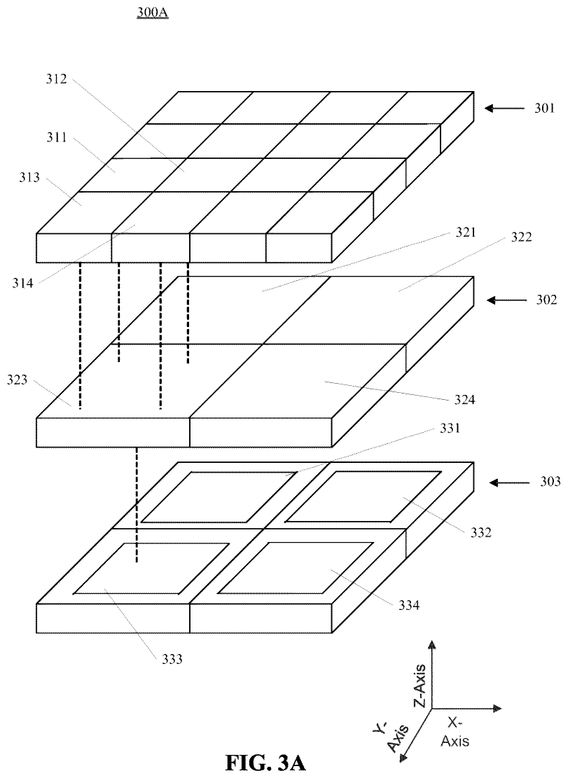

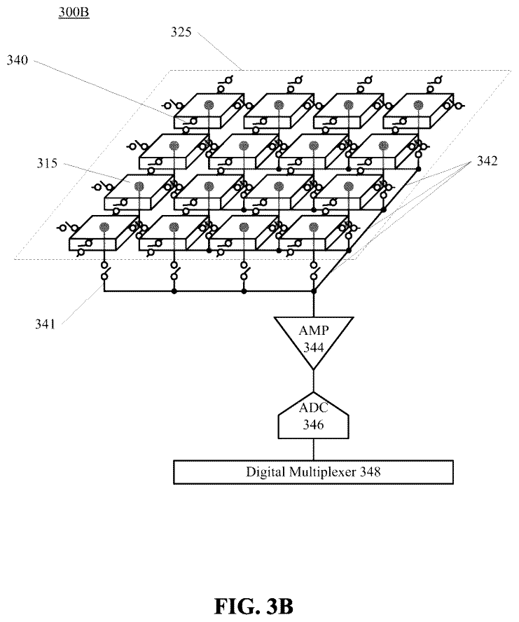

FIG. 3A illustrates an exemplary structure of a detector 300A, consistent with embodiments of the present disclosure. Detector 300A may be provided as an example of charged-particle detection device 244 shown in FIG. 2. In FIG. 3A, detector 300A includes a sensor layer 301, a section layer 302, and a readout layer 303. Sensor layer 301 may include a sensor die made up of multiple sensing elements, including sensing elements 311, 312, 313, and 314. In some embodiments, the multiple sensing elements may be provided in an array of sensing elements, each of which may have a uniform size, shape, and arrangement. Detector 300A may have an arrangement with respect to a coordinate axis reference frame. Sensor layer 301 may be arranged along an x-y plane. Sensing elements in sensor layer 301 may be arrayed in x-axis and y-axis directions. The x-axis direction may also herein be referred to as a “first lateral” direction. The y-axis direction may also herein be referred to as a “second lateral” direction. Detector 300A may have a layer structure in which sensor layer 301, section layer 302, and readout layer 303 are stacked in a z-axis direction. The z-axis direction may also herein be referred to as a “thickness” direction (e.g., a direction parallel to the thickness of a substrate on which the detector is formed). The z-axis direction may be aligned with a direction of incidence of charged particles that are directed toward detector 300A.

Section layer 302 may include multiple sections, including sections 321, 322, 323, and 324. The sections may include interconnections (e.g., wiring paths) configured to communicatively couple the multiple sensing elements. The sections may also include switches that may control the communicative couplings between the sensing elements. The sections may further include connection mechanisms (e.g., wiring paths and switches) between the sensing elements and one or more common nodes in the section layer. For example, as shown in FIG. 3A, section 323 may be configured to communicatively couple to outputs of sensing elements 311, 312, 313, and 314, as shown by the four dashed lines between sensor layer 301 and section layer 302. In some embodiments, section 323 may be configured to output combined signals gathered from sensing elements 311, 312, 313, and 314 as a common output. In some embodiments, a section (e.g., section 323) may be communicatively coupled to sensing elements (e.g., sensing elements 311, 312, 313, and 314) placed directly above the section. For example, section 323 may have a grid of terminals configured to connect with the outputs of sensing elements 311, 312, 313, and 314. In some embodiments, sections 321, 322, 323, and 324 may be provided in an array structure such that they have a uniform size and shape, and a uniform arrangement. Sections 321, 322, 323, and 324 may be square shaped, for instance. In some embodiments, an isolation area may be provided between adjacent sections to electrically insulate them from one another. In some embodiments, sections may be arranged in an offset pattern, such as a tile layout.

Readout layer 303 may include signal processing circuits for processing outputs of the sensing elements. In some embodiments, signal processing circuits may be provided, which may correspond with each of the sections of section layer 302. In some embodiments, multiple separate signal processing circuitry sections may be provided, including signal processing circuitry sections 331, 332, 333, and 334. In some embodiments, the signal processing circuitry sections may be provided in an array of sections having a uniform size and shape, and a uniform arrangement. In some embodiments, the signal processing circuitry sections may be configured to connect with an output from corresponding sections of section layer 302. For example, as shown in FIG. 3A, signal processing circuitry section 333 may be configured to communicatively couple to an output of section 323, as shown by the dashed line between section layer 302 and readout layer 303.

In some embodiments, readout layer 303 may include input and output terminals. Output(s) of readout layer 303 may be connected to a component for reading and interpreting the output of detector 300A. For example, readout layer 303 may be directly connected to a digital multiplexer, digital logic block, controller, computer, or the like.

The sizes of sections and the number of sensing elements associated with a section may be varied. For example, while FIG. 3A illustrates a 2×2 array of four sensing elements in one section, embodiments of the disclosure are not so limited. A section may comprise an array of, e.g., 3×3, 4×4, 1×6, or any desired number of sensing elements.

While FIG. 3A illustrates sensor layer 301, section layer 302, and readout layer 303 as multiple discrete layers, it is noted that sensor layer 301, section layer 302, and readout layer 303 need not be provided as separate substrates or dies. For example, a wiring path of section layer 302 may be provided in a sensor die including the multiple sensing elements, or may be provided outside of the sensor die. Wiring paths may be patterned on sensor layer 301. Additionally, section layer 302 may be combined with readout layer 303. For example, a semiconductor die may be provided that includes wiring paths of section layer 302 and signal processing circuits of readout layer 303. Thus, structures and functionalities of the various layers may be combined or divided.

In some embodiments, a detector may be provided in a two-die configuration. However, embodiments of the present disclosure are not so limited. For example, functions of a sensor layer, section layer, and readout layer may be implemented in one die or in a package that may contain one or more dies.

In some embodiments, arrangements of sensor layer 301, section layer 302, and readout layer 303 may correspond with one another in a stacked relationship. For example, section layer 302 may be mounted directly on top of readout layer 303, and sensor layer 301 may be mounted directly on top of section layer 302. The layers may be stacked such that sections within section layer 302 are aligned with signal processing circuitry sections (e.g., sections 331, 332, 333, and 334) of readout layer 303. Furthermore, the layers may be stacked such that one or more sensing elements within sensor layer 301 are aligned with a section in section layer 302. In some embodiments, sensing elements to be associated with a section may be contained within the section. For example, in a plan view of detector 300A, sensing elements (e.g., sensing elements 311, 312, 313, and 314) of a section (e.g., section 323) may fit within the boundaries of the section. Furthermore, individual sections of section layer 302 may overlap with signal processing circuitry sections of readout layer 303. In this manner, predefined areas may be established for associating sensing elements with sections and signal processing circuitry.

FIG. 3B is a diagram illustrating an exemplary detector array 300B with switches, consistent with embodiments of the present disclosure. Detector array 300B may be an example embodiment of detector 300A in FIG. 3A. For example, detector array 300B may include a sensor layer (e.g., similar to sensor layer 301 in FIG. 3A), a section layer (e.g., similar to section layer 302 in FIG. 3A), and a readout layer (e.g., similar to readout layer 303 in FIG. 3A). The sensor layer of detector array 300B may include multiple sensing elements 315. In some embodiments, each of the sensing elements 315 of detector array 300B may have a uniform size, shape, and arrangement. The sensing elements of detector array 300B may generate an electric current signal commensurate with the charged particles (e.g., exiting electrons) received in the active areas of the sensing elements. The “active areas” herein may refer to areas of the sensing elements having radiation sensitivity above a predetermined threshold value.

The section layer of detector array 300B may include a base substrate (e.g., a semiconductor substrate, not shown in FIG. 3B) including one or more wiring paths 342. Wiring paths 342 may be configured to communicatively couple the sensing elements of detector array 300B. As shown in FIG. 3B, detector array 300B includes a section 325 having a 4×4 array of sensing elements 315. The 4×4 array of section 325 may have a similar architecture to the 2×2 arrays in any of sections 321-324 of FIG. 3A. In FIG. 3B, the section layer of detector array 300B may include inter-element switches 340 between any two adjacent sensing elements 315. The section layer of detector array 300B may also include inter-element switches 340 communicatively coupled to neighboring sensing elements on the edge of neighboring sections. Wiring paths 342 may be configured to communicatively couple to outputs of sensing elements 315 in section 325. For example, wiring paths 342 may have a grid of terminals (shown as round black dots at the centers of the sensing elements) configured to connect with the outputs of sensing elements 315. In some embodiments, wiring paths 342 may be provided in the section layer of detector array 300B. In FIG. 3B, wiring paths 342 are communicatively coupled to the above sensing elements 315. In FIG. 3B, element-bus switches 341 may be provided between the outputs of the sensing elements and wiring paths 342. In some embodiments, the element-bus switches may be provided in the section layer of detector array 300B.

In some embodiments, wiring paths 342 may include lines of conductive material printed on the base substrate, flexible wires, bonding wires, or the like. In some embodiments, switches may be provided so that outputs of individual sensing elements can be connected or disconnected with the common output of section 325. In some embodiments, the section layer of detector array 300B may further include corresponding circuits for controlling the switches. In some embodiments, switches may be provided in a separate switch-element matrix that may itself contain circuits for controlling the switches.

The readout layer of detector array 300B may include signal conditioning circuits for processing outputs of the sensing elements. In some embodiments, the signal conditioning circuits may convert the generated current signal into a voltage that may represent the intensity of a received beam spot, or may amplify the generated current signal into an amplified current signal. The signal conditioning circuit may include, for example, an amplifier 344 and one or more analog switches (not shown in FIG. 3B). The amplifier 344 may be a high speed transimpedance amplifier, a current amplifier, or the like. In FIG. 3B, amplifier 344 may be communicatively coupled to the common output of section 325 for amplifying the output signals of the sensing elements of section 325. In some embodiments, amplifier 344 may be a single-stage or a multi-stage amplifier. For example, if amplifier 344 is a multi-stage amplifier, it may include a pre-amplifier and a post-amplifier, or include a front-end stage and a post stage, or the like. In some embodiments, amplifier 344 may be a variable gain amplifier, such as a variable gain transimpedance amplifier (VGTIA), a variable gain charge transfer amplifier (VGCTA), or the like. The conditioning circuit may be coupled to a signal path that may include, for example, an analog-to-digital converter (ADC) 346. In FIG. 3B, ADC 346 may be communicatively coupled to the output of the conditioning circuit (e.g., including amplifier 344) to convert the analog output signals of the sensing elements of section 325 to digital signals. The readout layer of detector array 300B may also include other circuits for other functions. For example, the readout layer of detector array 300B may include switch-element actuating circuits that may control the switches between the sensing elements. For ease of explanation without causing ambiguity, the signal path between the sensing elements and ADC 346 may be referred to as an “analog signal path.” For example, the analog signal path in FIG. 3B includes the above-described signal conditioning circuit (e.g., including amplifier 344). The input of the analog signal path is communicatively coupled to the sensing elements, and the output of the analog signal path is communicatively coupled to ADC 346.

In some embodiments, ADC 346 may include output terminals communicatively coupled to a component (e.g., a component inside or outside the readout layer of detector array 300B) for reading and interpreting the digital signal converted by ADC 346. In FIG. 3B, ADC 346 is communicatively coupled to a digital multiplexer 348. In some embodiments, digital multiplexer 348 may be arranged in the readout layer of detector array 300B. Digital multiplexer 348 may receive multiple input signals and convert them as an output signal. The output signal of digital multiplexer 348 may be converted back to the multiple input signals. The output signal of digital multiplexer 348 may be further transmitted to a data processing stage (e.g., image processing system 290 in FIG. 2). Further details of the detector arrangement of FIGS. 3A-3B may be found in the previously incorporated International Publication No. WO 2021/239754 A1, and in International Publication No. WO 2021/219519 A1, the entirety of which is incorporated herein by reference.

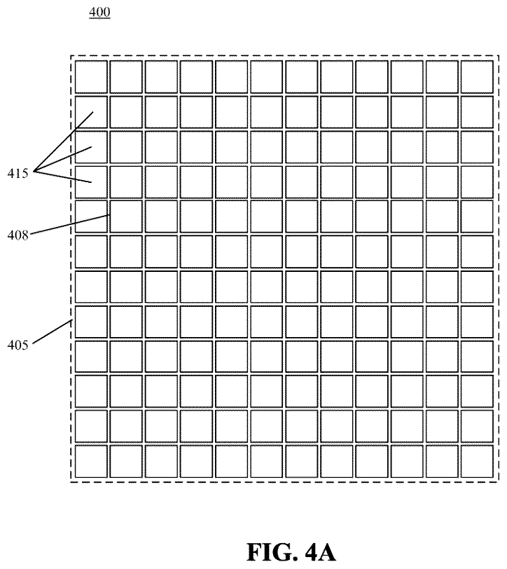

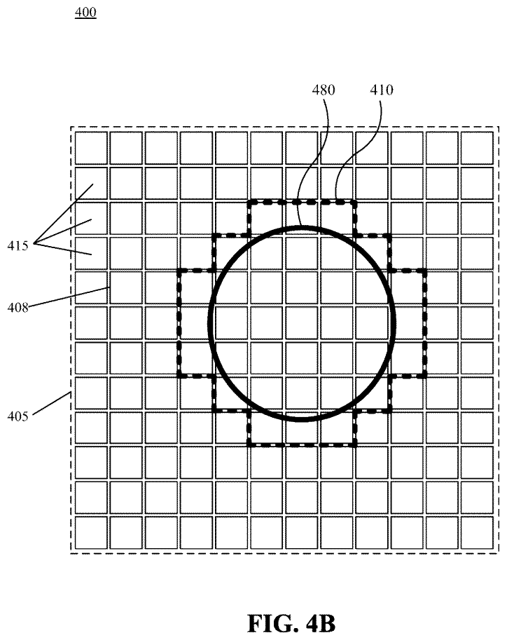

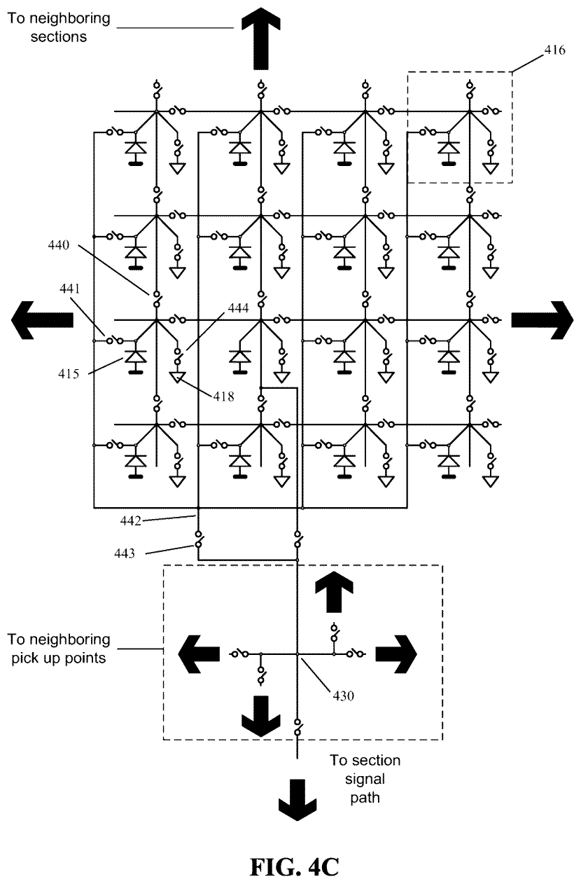

FIGS. 4A-B illustrate a detector 400 surface and picture mode operation according to a comparative embodiment. FIG. 4A illustrates a surface of a detector 400. Detector 400 in this comparative embodiment may correspond to a detection surface of charged-particle detection device 244 or detector 300A or 300B. The detection surface may comprise an array of sensing elements, such as PIN diode elements. In some embodiments, sensing elements may include, e.g., an avalanche diode, an electron multiplier tube (EMT), or other components. Each of the sensing elements (e.g., PIN diodes) may correspond to a discrete sensing element 415. Alternatively, a single sensing element (e.g., a PIN diode) may be pixelated into separate sensing elements 415 in various ways. For example, semiconductor detection cells may be divided by virtue of internal fields generated due to internal structures. In some embodiments, there may be physical separation between adjacent sensing elements, such as by area 408 provided between adjacent sensing elements. Area 408 may be an isolation area to isolate the sides or corners of neighboring sensing elements from one another. In some embodiments, area 408 may include an insulating material that is different from that of the sensing elements 415 on the sensor surface of detector 400. In some embodiments, area 408 may be provided as a square. In some embodiments, area 408 may not be provided between adjacent sides of sensing elements.

As shown in FIG. 4A, there may be a region of interest 405 on surface of detector 400. A pixelated array of sensing elements on a detector may make up region of interest 405. In some embodiments, there may be more sensing elements provided in the detector outside of region of interest 405. Region of interest 405 may be a portion of the detector.

FIG. 4B illustrates a picture mode operation according to a comparative embodiment. A secondary beam spot 480 formed on the surface of the detector 400 of FIG. 4A, according to a comparative embodiment. Beam spot 480 may have a well-defined center, or locus. Although beam spot 480 is illustrated as having an approximately round shape, a distribution of secondary particles landing within beam spot 480 may have an irregular shape and may deviate substantially from an ideal round shape. Some regions of beam spot 480 may receive more secondary particles than others. Secondary particles may be generated in response to incidence of a primary beam on a sample and may be emitted with a variety of energy and emission angles. The secondary particles may form a beam (e.g., a secondary electron beam). The secondary electron beam may be incident on the detector and may form beam spot 480.

Furthermore, as shown in FIG. 4B, a boundary 410 may be determined. Boundary 410 may be provided so as to encompass sensing elements that receive charged particles from the secondary electron beam. The sensing elements contained within boundary 410 may be covered, at least partially, by the same charged particle beam spot. Boundary 410 may include a border of beam spot 480. As used herein, the term “boundary” may refer to an outer perimeter encompassing a beam spot as encoded by a detector. The shape of the boundary may conform to the shapes of individual sensing elements 415. A “border” may refer to an outline of a beam spot. The border of a beam spot may more closely correspond to a natural shape formed by charged particles of a beam impinging on a surface. For example, a beam spot may have an approximately round border and a more square boundary surrounding the border. In some embodiments, the border and boundary may coincide.

Determining a beam spot boundary may be based on an acquired beam spot projection pattern. A beam spot projection pattern may be acquired by reading individual outputs of sensing elements that may be included in a detector. In a “picture” mode, an image of the detector surface may be acquired, and a boundary or grouping of sensing elements associated with a beam spot may be determined. During picture mode, a detection system may be dedicated to projection pattern acquisition. It may be determined, for example, that electrons are being received in a group of sensing elementson the detector surface 400. The group of sensing elements may be continuous and may have a substantially round shape. A beam spot boundary 410 may be drawn around the sensing elements in the group. Each of the sensing elements within the boundary may be receiving electrons at least partially within the surface area of the sensing element. Sensing elements included in the group may be used for later processing, such as beam spot intensity determination (e.g., using a “beam” mode). Other processing in the picture mode may include pattern recognition, edge extraction, etc. In some embodiments, beam spot 480 may deviate from a round shape. For example, beam spot 480 may have an elongated shape. When beam spot 480 changes shape or drifts across detector surface 400, a new boundary 410 may be determined that corresponds to the new shape or location, and a new grouping of sensing elements associated with beam spot 480 may be updated accordingly. However, because the detector cannot detect the spatial location of an electron landing event within any given sensing element 415, the minimum resolution of beam spot boundary 410 is determined by the size of one sensing element 415.

After a boundary 410 is determined for a beam spot in picture mode, sensing elements within the boundary may be grouped together during normal operation, such as an inspection process, in beam mode. The grouped elements may be functionally coupled so that an intensity measured at the grouped sensing elements within boundary 410 are determined to correspond to a beam parameter, such as intensity, of secondary beam spot 480. Grouping is determined in discrete sensing element units . . . Therefore the image resolution of the detector in picture mode (picture mode resolution) and the grouping resolution of the detector in beam mode (beam mode resolution) are the same. Further details of picture mode and beam mode operations may be found in U.S. Provisional Application No. 63/130,576, the entirety of which is incorporated herein by reference.

FIG. 4C is a diagrammatic representation of a 4×4 section of sensing elements 415 in a detector chip circuit design according to a comparative embodiment. The arrangement may correspond to a 4×4 array of sensing elements 415 in FIGS. 4A-B, with each sensing element circuit 416 corresponding to a unit cell comprising a sensing element 415 along with associated switching elements and other circuitry. Multiple sections of the same structure are repeated in the detector chip, and neighboring sections are interconnected with each other as indicated by the long arrows. Between each two adjacent sensing elements, a group switch 440 is placed so that the detector chip can achieve a grouping function in the beam mode. The switch may correspond to switches 340 in FIG. 3B. In addition, between each sensing element 415 and a common signal bus 442, an element-bus switch 441 is placed to enable individual sensing element addressing in picture mode. A signal bus 442 may be, e.g., wiring paths 342 as described with respect to FIGS. 3A-B. Common signal bus 442 is further connected to a junction node 430 and neighboring pickup points of other circuit sections as indicated by the short arrows at the bottom of FIG. 4C. The connection to the junction node and neighboring pickup points may be made via a section switch 443.

Between each sensing element 415 (e.g., a PIN diode) and a signal ground or common voltage 418, there may be a ground switch 444 configured to release charge from the sensing element circuit 416 when it is not in use. When a sensing element is not in use, ground switch 444 may be closed so that there is no charge accumulation on the sensing element circuit 416 due to, e.g., a secondary electron beam spot being fully or partially incident upon the sensing element. Such charge accumulation may lead to detector malfunction or damage. When a switch is “closed” both sides of the switch are electrically connected, and when a switch is “open” both sides of the switch are isolated from each other.

When a detector operates in picture mode, a charged particle beam (e.g., a secondary electron beam) may irradiate a plurality of sensing elements. To determine which sensing elements are being irradiated by the beam, each element-bus switch 441 on a common signal bus 442 may be closed one at a time. During a given time period there may be only one sensing element coupled to each readout signal path. In this way, a signal output reaching a signal processing circuit during that time period may be uniquely identified as belonging to a particular sensing element. By successively coupling and decoupling each sensing element in a section of the detector to a common signal bus 442 for that section, detection information about each sensing element 415 may be obtained. Thus, a detector may be controlled (e.g., by controller 109 or image processing system 290) to determine a spatial distribution of sensing elements 415 upon which beam spot 480 is incident, and to use that spatial distribution to construct boundary 410, as seen in FIG. 4B. While each individual readout path can only read one sensing element at a time, a detector in picture mode may still read out multiple sensing elements in parallel by using multiple signal readout paths to speed up the image capture process. Additionally, pixel binning may be performed. Pixel binning may involve combining signals from more than one sensing element at a time when transmitting the signals to the output bus. Pixel binning may be useful for obtaining a relatively lower resolution image of the secondary beam projection pattern at relatively higher speed. Pixel binning may comprise using switches between sensing elements and the bus to connect more than one sensing element to the bus at a time. Pixel binning may comprise using inter-element switching elements to connect sensing elements to be binned together. Then, any of the element-bus switching elements connected to the binned sensing elements may be actuated to connect the binned sensing elements to the bus. Sensing elements may be binned in any shape or number during a picture mode operation.

In theory, using ideal switches and sensing elements, the circuit design of FIG. 4C could achieve great configuration flexibility without a performance penalty. For instance, the same repeating circuit designs could be drastically reduced in size and multiplied to enable higher resolution without any degradation of other performance parameters. However, real analog switches and sensing elements suffer from parasitic parameters. For example, the speed or analog bandwidth of the system may be reduced due to, e.g., parasitic capacitance. For this reason, the additional section switch 443 may be added between common signal bus 442 and junction node 430, where the junction node leads to a pickup point and the input of the readout circuitry within each section. The purpose of this switch is to isolate the parasitic capacitance from the sensing elements and their corresponding picture mode switches that are not in use when the detector 400 is operated in beam mode so that the analog bandwidth can be improved. But if the size of sensing elements 415 are made smaller to increase the sensing element density (with corresponding improvement in resolution), the amount of switches needed for grouping purposes (e.g., switches 440 that connect adjacent sensing elements 415) will increase proportionately. Therefore, the parasitic capacitance due to the increased number of switches and sensing elements may increase. Furthermore, higher overall switch counts may increase the parasitic resistance (series resistance) due to a greater number of switches that are placed in series. All this may cause analog bandwidth reduction when the detector is operating in beam mode. This then may cause SEM images that are blurry compared to detectors having fewer circuit components under the same SEM pixel rate. Throughput may be reduced due to a lower usable SEM pixel rate to avoid such blurring. Thus, from the perspective of system throughput and analog bandwidth of the detection channel, there is a functional limit on the minimum allowable size of sensing elements in the layout of FIG. 4C.

However, there may be a desire for higher resolution secondary electron beam spot images that may be useful in SEM system tuning and picture mode element grouping. The high resolution images can provide more information about a secondary electron beam spot on the detector surface. This may help improve the SEM system tuning results and enable better element grouping decisions. This higher resolution may require a sensing element size in picture mode that is smaller than what the detector architecture of FIG. 4C can provide.

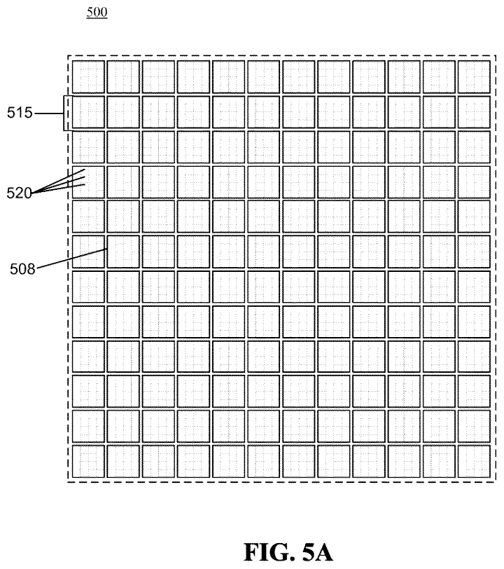

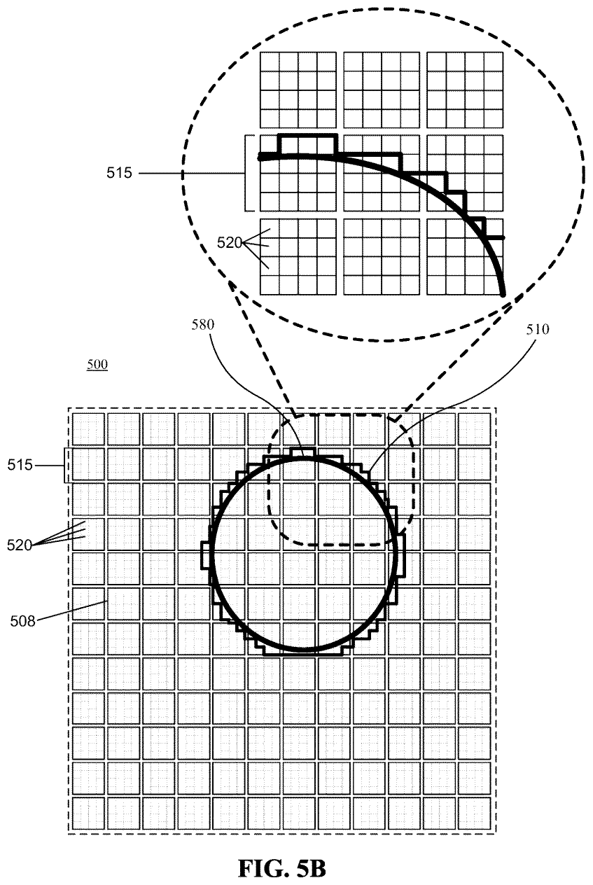

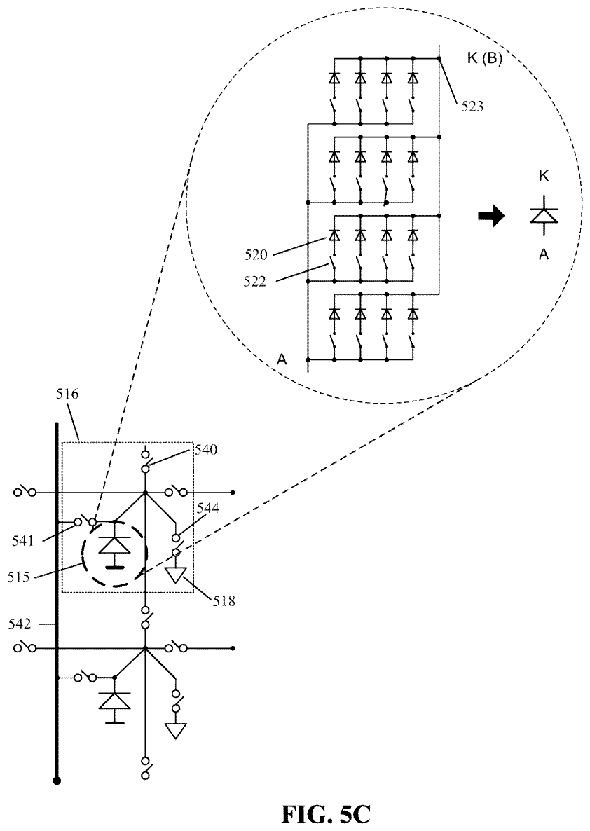

FIG. 5A illustrates a surface of a detector 500 that may address one or more of the challenges above, consistent with embodiments of the present disclosure. Detector 500 may be a detection surface of charged-particle detection device 244 or detector 300A or 300B. Detector 500 may comprise an array of sensing elements 515. The overall switch matrix design and the circuit design in FIGS. 5A-5C may appear similar to that of FIGS. 4A-4C when viewing the system at a hierarchy greater than the sensing element level. But an examination at the level of a singular sensing element 515 reveals a different architecture. In the comparative embodiment of FIGS. 4A-4C, a sensing element 415 is the minimum unit pixel size detectable on detector 400. In embodiments of the present disclosure at FIGS. 5A-5C, sub-sensing elements 520 are introduced to each sensing element 515 for resolution enhancement in picture mode. The new design has almost no impact on analog bandwidth in beam mode. This helps to eliminate the need for a tradeoff between secondary electron projection image resolution in picture mode and analog bandwidth or SEM image pixel rate in beam mode. In some embodiments as further discussed below, the new design may offer additional resolution capabilities in beam mode as well.

As seen in FIG. 5A, detector 500 may comprise an array of sensing elements 515, where the sensing elements may be further sub-divided into sub-sensing elements 520. For instance, a sensing element 515 may comprise a 4×4 grid array of sub-sensing elements 520. In practice, any arrangement of sub-sensing elements is possible. For example, there may be more or fewer sub-sensing elements, and they need not be arranged in a square or even rectangular array. In some embodiments, the arrays of sub-sensing elements 520 may occupy substantially an entire area of element 515 between isolation areas 508. In some embodiments, area 508 may not be provided between adjacent sides of sensing elements 515. Each sub-sensing element 520 within a sensing element 515 may be addressed individually as described further below.

FIG. 5B illustrates a secondary beam spot 580 formed on the surface of detector 500 of FIG. 5A, consistent with embodiments of the present disclosure. Secondary beam spot 580 may be similar to secondary beam spot 480 of FIG. 4B. However, because detector 500 comprises arrays of individually addressable sub-sensing elements 520, a boundary 510 may be determined for secondary beam spot 580 with a much higher resolution than boundary 410 around secondary beam spot 480. During a picture mode operation, each sub-sensing element 520 within a sensing element 515 may be individually addressed to detect whether an electron landing event has occurred at the precise location of the sub-sensing element. A higher precision boundary 510 may then be determined at the resolution level of sub-sensing elements 520. The upper right portion of FIG. 5B shows the difference more clearly in a close-up of a 3×3 section of sensing elements 515 comprising sub-sensing elements 520.

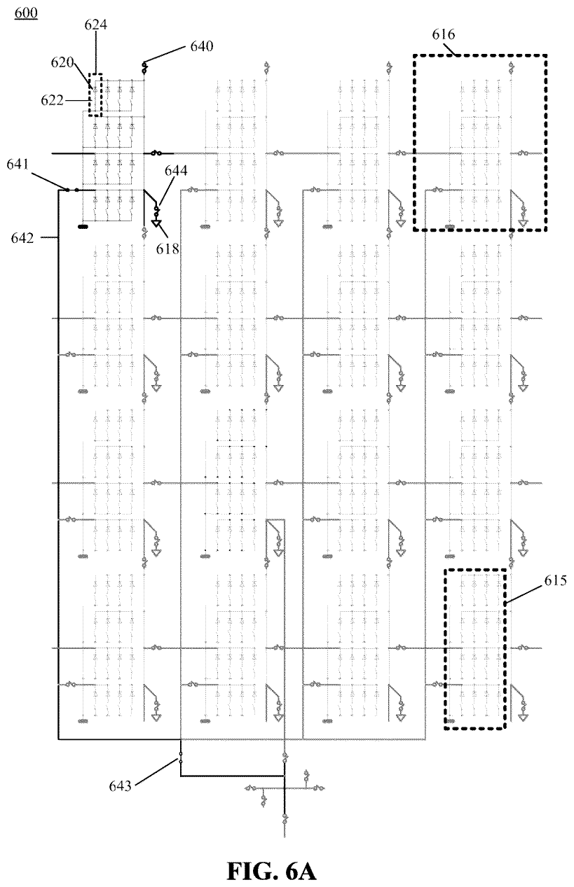

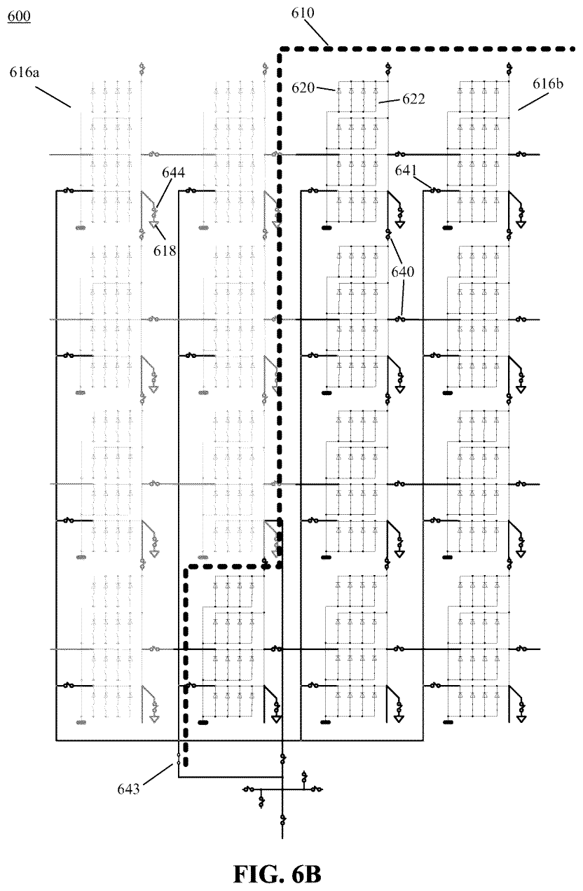

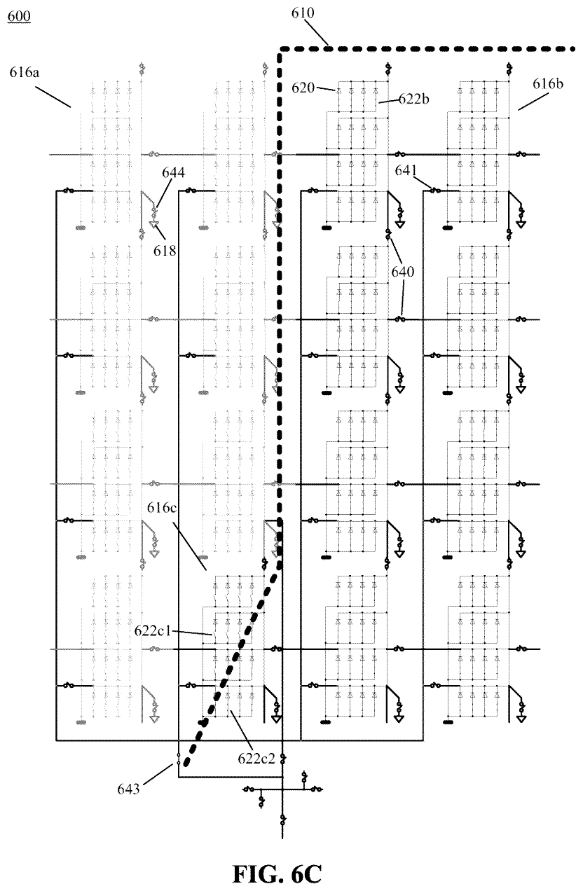

The higher precision boundary 510 obtained using sub-sensing elements 520 may be used to determine an appropriate grouping of sensing elements 515 during beam mode. In some embodiments of the present disclosure, it may also be used to determine a partial sensing element for grouping in the beam mode. For example (as discussed below with respect to FIG. 6C), a sensing element 515 on the periphery of a grouping of sensing elements may activate only a portion of its sub-sensing elements 520 during beam mode in order to adhere more closely to the shape of the beam spot 580.

FIG. 5C is a diagrammatic representation of a sub-sensing element detector architecture, consistent with embodiments of the present disclosure. Sensing elements 515 may correspond to, e.g., sensing elements 311-314 in FIG. 3A, sensing elements 315 in FIG. 3B, or sensing elements 415 in FIGS. 4A-4B. The detector chip circuit design may form part of a detector such as, e.g., detectors 300A, 300B or 500. A sensing element circuit 516 may comprise some features that are similar to sensing element circuit 416 of FIG. 4C. For instance, sensing element circuit 516 and related circuitry may comprise: group switches 540 between adjacent sensing elements for grouping the adjacent sensing elements in a beam mode; an element-bus switch 541 for connecting to signal bus 542 to enable individual sensing element addressing in picture mode; a section switch (not shown) between the common signal bus 542 and a junction node to a pickup point and the input of the readout circuitry within each section; and a ground switch 544 between each sensing element and a signal ground or common voltage 518, configured to release charge from the sensing element circuit 516 when it is not in use. However, unlike sensing element 415 of FIG. 4B, sensing element 515 may subdivided into an array of smaller sub-sensing elements 520. Sub-sensing elements 520 may be, e.g., PIN diodes or any other suitable sub-sensing element that may convert a charged particle landing event into a measurable signal. A charged particle landing event may reflect information such as energy of an incident charged particle, timestamp of landing, number of charged particles landing within a time period, or any information indicating properties of charged particles landing on the detector. Further, as shown in the closeup in FIG. 5C, each sub-sensing element 520 may be coupled to a sub-element switch 522 on a first side and a sensing element node 523 on a second side. As shown, the sub-element switches 522 are located on the bias side of sub-sensing elements 520. However, switches may alternatively be located on a signal side.

When the detector operates in picture mode, each sensing element 515 may be individually selected by successively connecting and disconnecting each sensing element 515 to common signal bus 542 via its element-bus switch 541. However, while a sensing element 515 is selected, each of its sub-sensing elements 520 may also be addressed individually. By closing each sub-element switch 522 one at a time, only one sub-sensing element 520 will be connected to provide signal output. The signal output may correspond to a single sub-pixel in a high resolution image, and may be referred to as a picture mode sub-pixel signal. A controller (e.g., controller 109 or image processing system 290) may electronically scan an entire detector using a combination of section level addressing switches (e.g., successively connecting each sensing element 515) and the sensing-element level address switches (e.g., successively connecting each sub-sensing element 520 within the sensing elements 515). Thus, a high resolution secondary electron beam spot image may be captured on the detector surface. Detector 500 may be configured such that it can still read out multiple sensing elements in parallel in picture mode as existing detectors may do when multiple readout signal paths are used for speeding up the image capture process. But within a section connected to one readout signal path, because all sub-sensing elements 520 within a sensing element 515 share a common sensing element node 523, improved resolution may be achieved by addressing one sub-sensing element 520 at a time via its respective sub-element switch 522. Although the individual addressing of sub-sensing elements may require more time than a comparative embodiment having no sub-sensing elements, the higher resolution image may outweigh this and other concerns. Speed may be more important during a beam mode operation, as discussed below. High resolution imaging may be beneficial for SEM tuning and alignment, as well as for sensing element grouping.

Additionally, sub-pixel binning may be performed in an analogous manner to the pixel binning discussed above with respect to FIG. 4C of the comparative embodiment. For example, to increase readout speed in exchange for a corresponding lower resolution, more than one sub-sensing element 520 may be addressed at a time within a single sensing element 515. Sub-sensing elements 520 may be binned in any shape, and they need not be immediately adjacent to one another.

FIGS. 6A-6B illustrate examples of a 4×4 section of sensing elements in a detector chip circuit design consistent with embodiments of the present disclosure. A sensing element 615 is shown in the dashed box in the lower right corner of FIG. 6A, while a sensing element circuit 616 is shown in the dashed box at the upper right corner. Sensing elements 615 may correspond to, e.g., sensing elements 311-314 in FIG. 3A, sensing elements 315 in FIG. 3B, or sensing elements 515 in FIGS. 5A-5B. Sensing element circuits 616 may be a unit cell comprising a sensing element 615 along with associated switching elements and other circuitry. Multiple sensing element circuits 616 are provided as repeating unit cells. The detector chip circuit design may form part of a detector such as, e.g., detectors 300A, 300B or 500.

FIG. 6A illustrates the 4×4 section during a picture mode operation. At the moment depicted in the figure, only the upper leftmost sensing element circuit 616 is in communication with a signal path by way of closed element-bus switch 641 and section switch 643. Furthermore, within the sensing element circuit, as shown at the dashed-line box 624, there may be only one sub-sensing element 620 in communication with the signal path by closing its respective sub-element switch 622. If a portion of a secondary electron beam is incident at the location of the one connected sub-sensing element 620, then a signal may be communicated to a signal processing circuit of the detector. The signal may indicate that the location is being irradiated by the secondary electron beam (e.g., including by comparing the signal to a threshold value, by applying filtering to eliminate e.g., noise or dark current). By scanning each sub-sensing element 620 of each sensing element 615, a high-resolution image may be obtained. The image may be applied to a sensing element grouping algorithm, used for SEM tuning/alignment, or otherwise used to enhance operation of a charged particle beam apparatus. It is noted that other switches may be open or closed in some embodiments. For instance, the unused sensing element circuits 616 may have their ground switches 644 closed in order to avoid charge accumulation. Additionally, if multiple readout paths are available, other sensing elements 616 may be scanning through their respective sub-sensing elements 620 at the same time as the upper left sensing element circuit shown in FIG. 6A.

FIG. 6B illustrates the 4×4 section during a beam mode operation, consistent with some embodiments of the present disclosure. For example, the beam mode operation may be a SEM inspection. After performing a picture mode operation as discussed with respect to FIG. 6A, a boundary 610 may be determined for sensing element grouping. Here, sensing element circuits 616a on the left side of boundary 610 (depicted in gray) are outside the boundary, while sensing element circuits 616b on the right side of boundary 610 (depicted in black) are inside. Sensing element circuits 616a may be deactivated. For example, sensing element circuits 616a may be deactivated by closing all sub-element switches 622 as well as ground switch 644 to send any received charge to ground, or by opening all sub-element switches 622 to decouple their sub-sensing elements 620 from a signal readout path. In general, there are many switching arrangements that may effectively deactivate a sensing element circuit. Sensing element circuits 616b inside the boundary may be activated by closing all sub-sensing sub-element switches 622 to couple their sub-sensing elements 620 to a signal readout path. The signal output from a sensing element circuit 616b may correspond to the signal output from a single sensing element circuit 416 in FIG. 4C, and may be referred to as a beam mode sensing element signal.

During a beam mode operation when all sub-element switches 622 of a sensing element circuit 616 are closed, the array of independent sub-sensing elements 620 operate as a single conversion element, such as sensing element 415 of FIG. 4C, for converting a charged particle landing event into a signal. For example, the array of connected sub-sensing elements 620 may operate in a manner similar to the larger sized sensing element 415 of the comparative embodiment. Therefore, a maximum resolution in a picture mode may be higher than a maximum resolution in beam mode.

While the arrangement of FIGS. 6A-6B does have a higher switch count in order to enable the high resolution picture mode, parasitic parameters may be minimized by the highly parallel architecture. For example, since the combinations of switches at the sensing element and sub-sensing element level in a sensing element array are in parallel, the impact of series resistance due to the added switches on analog bandwidth in beam mode may be reduced, eliminated, or considered negligible.

FIG. 6C illustrates the 4×4 section during a beam mode operation, consistent with some embodiments of the present disclosure. The embodiment of FIG. 6C may be similar to the embodiment of FIG. 6B except as described herein. A partial sensing element circuit 616c may be implemented in beam mode. As shown at the bottom of FIG. 6C, boundary 610 may be drawn directly through the array of sub-sensing elements 620 in sensing element circuit 616c. Outer sub-sensing element switches 622c1 of the partial sensing element 616c, located outside boundary 610, may be open. Inner sub-sensing element switches 622c2 of the partial sensing element 616c, located inside boundary 610, may be closed. Only those sub-sensing elements 620 that are connected by inner sub-sensing element switches 622c2 may be coupled to a signal readout path. In this way, a more complex boundary may be drawn that more closely corresponds to a beam spot, such as beam spot 580 in FIG. 5B. For example, sensing elements located on boundary 610 may be implemented as partial sensing elements to achieve a stepped or more complex profile for the portion of boundary 610 that passes through it. Additionally, boundary 610 may include a simple horizontal or vertical line that passes through an interior portion of a sensing element 615 instead of around its edge. Partial sensing element arrangements may be beneficial, e.g., to reduce crosstalk when two beam spots are close to each other. A signal output from a sensing element circuit 616c may be referred to as a beam mode partial sensing element signal. In some embodiments of the present disclosure using beam mode partial sensing elements, the maximum resolution in beam mode may be equal to a maximum resolution in picture mode.

While the discussion above is focused on the state of switches 622, it is noted that other switches may be altered from their depicted orientation. For instance, various combinations of group switches 640 may be closed to group sensing element circuits 616b together. One or more element-bus switches 641 may be closed to connect the grouped sensing element circuits 616b to a signal readout path. Further, unused sensing element circuits 616a may be connected to a signal ground or common voltage 618 by ground switches 644. Furthermore, in the configuration shown in FIG. 6B, sub-element switches 622 are placed on a bias voltage side, and so the impact from parasitic capacitance of the switches can also be reduced, eliminated, or considered negligible. In some embodiments, bias side switches may be implemented using traditional manufacturing techniques in the semiconductor chip that forms the detector. For example, ion implantation, deposition, etching (e.g., deep reactive-ion etching) or other techniques may be used for creating circuit elements. However, other switch configurations are contemplated in some embodiments of the present disclosure.

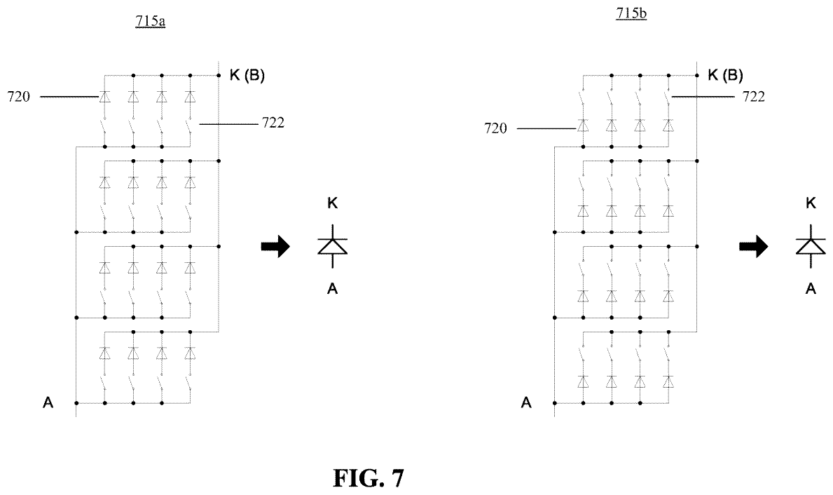

FIG. 7 illustrates two possible switch configurations for sub-sensing elements, consistent with embodiments of the present disclosure. On the left is the bias side arrangement 715a for sub-element switches 722, also demonstrated in FIGS. 6A-6B. On the right is a signal side arrangement 715b for sub-element switches 722. A bias side of a sub-sensing element 720 may refer to a side of the sub-sensing element where bias voltage is applied to the detector in operation. A detector may operate with bias voltage applied across the sub-sensing element so that charge carriers generated within the sub-sensing element (as a result of an electron landing event) are swept to one side or the other, allowing signals to flow out of the sub-sensing element. A signal side may refer to a side of the sub-sensing element where signal flows in or out. The signal side may coincide with the incidence side of the detector. The bias side implementation 716a may minimize parasitic capacitance from the switches. The implementation of 716b may allow placement of all circuit components and related connections on one side of the detector chip, which may reduce the chip processing requirements, resulting in lower manufacturing costs.

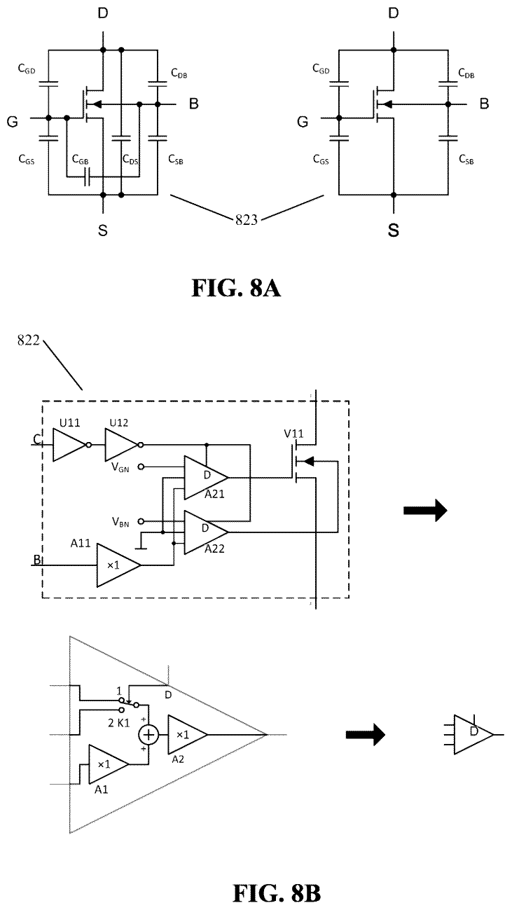

In addition to switch placement, parasitic parameters may be further reduced by the switch design. FIG. 8A illustrates the parasitic capacitance of a MOSFET 823, which is a key component in some analog switch designs, comprising gate G, bulk B, source S and drain D. The left and right sides of FIG. 8A show the parasitic capacitance of a MOSFET in the off and on states, respectively. The parasitic capacitances C_{GD} between gate G and drain D, C_{GS} between gate G and source S, C_{DB} between bulk B and drain D, and C_{SB} between bulk B and source S need only be considered when the switch is on. FIG. 8B illustrates a simplified circuit schematic of an analog switch design 822 comprising the MOSFET design of FIG. 8A. A bootstrapping technique may be used to reduce parasitic capacitances from the MOSFET in signal-side analog switches.

In some embodiments of the present disclosure, a detector may be configured to select a preferred balance between resolution and signal readout speed. The signal read out speed in picture mode may decrease as resolution increases, because, for example, it may take longer to individually address a larger number of sub-sensing elements. Therefore, in some embodiments of the present disclosure, it may be advantageous to group sub-sensing elements together into sub-groups in order to reduce the number of individual sub-sensing element readouts that must take place.

For example, it may be preferable to divide the alignment process of a secondary column of a multi-beam tool into coarse and fine tuning phases. Initially, during a coarse tuning phase, resolution may be lowered through the above sub-sensing element grouping in order to achieve a higher readout speed. This may enable rapid feedback adjustment of elements in the secondary column to speed up the coarse tuning. When coarse tuning adjustments are complete, a fine tuning phase may be implemented. The fine tuning phase may allow a lower readout speed in favor of higher resolution by actuating sub-sensing elements individually or in smaller groupings to increase the feedback accuracy. Using coarse and fine tuning phases, secondary column adjustment may be achieved quickly and accurately.

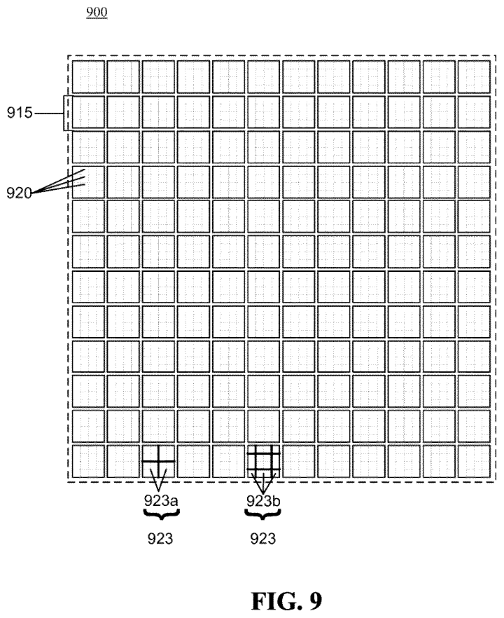

FIG. 9 illustrates two possible examples of sub-groups 923 (e.g., 923a and 923b) of sub-sensing elements 920 in a picture mode that may achieve a higher readout speed, consistent with embodiments of the present disclosure. Sub-groups 923 may be achieved by closing more than one sub-element switch at a time during a picture mode operation. Each sub-group 923 then outputs the merged (e.g., summed) signal of its sub-sensing elements 920. In FIG. 9, a sensing element 915a is divided into a set of uniform sub-groups 923a, each having four sub-sensing elements 920. Because the four sub-sensing elements 920 are connected to a sensing element node simultaneously, the output signals within that sub-group are coupled. The coupled signals may be referred to as a picture mode sub-group pixel signal. A picture-mode operation may be carried out by successively addressing each subgroup 923a within sensing element 915a rather than addressing each of the sub-sensing elements 920 individually. Thus, a reduction (e.g., 75% here) in the number of individual addressing steps leads to an improvement in picture mode readout speed.

The sub-sensing elements can also be divided into non-uniform groups, such as in sub-groups 923b. As shown on the right in FIG. 9, sub-sensing elements 920 inside sensing element 915b are classified into nine sub-groups 923b. One sub-group has four sub-sensing elements 920, four sub-groups each have two sub-sensing elements 920, and four sub-groups each have one sub-sensing element 920. Any suitable arrangement of sub-groups 923 may be chosen. The arrangements need not be rectangular, and the grouped sub-sensing elements 920 need not be adjacent. By way of example, a first sub-group 923 could be composed of the four sub-sensing elements 920 located at the corners of a sensing element 915, and a second sub-group 923 could be a cross-shaped sub-group composed of the remainder.

It should be understood that the above grouping configurations could be achieved by manufacturing a detector with fewer sub-elements than the illustrated 4×4 examples. For instance, the sub-group 923a may be achieved by a 2×2 array of sub-sensing elements 920. The sub-group 923b may be achieved by a 3×3 array of differently sized sub-sensing elements 920. The illustration of FIG. 9 demonstrates a dynamic capability to adjust groupings. This may be used to select, on demand, a preferred tradeoff between speed and resolution.

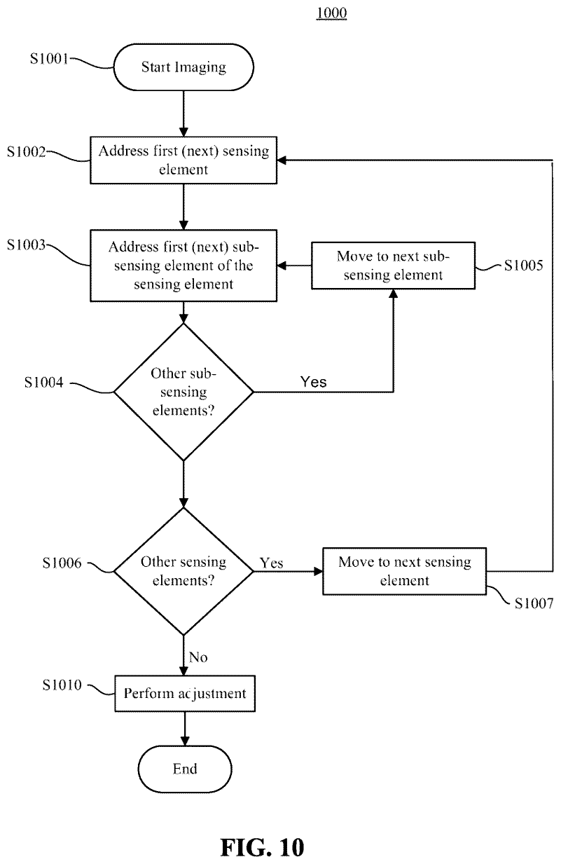

FIG. 10 illustrates a method 1000 of using a detector having sub-sensing elements, consistent with embodiments of the present disclosure. The detector may comprise detectors or elements disclosed in FIGS. 1, 2, 3A-3B. 5A-5C, 6A-6B, 7 or 8A-8B.

In step S1001, an imaging process is initiated in a charged particle beam apparatus. The charged particle beam apparatus may be, e.g., a SEM. The charged particle beam apparatus may be a beam tool 104 of FIGS. 1-2. The imaging process may be a picture mode operation used for, e.g., sensing element grouping in a beam mode, SEM tuning or alignment, or any other process for which a high-resolution image of a beam spot is desired. A primary charged particle beam (e.g. an electron beam) irradiates a surface and a resultant secondary beam (e.g., a beam of secondary or backscattered electrons) is projected onto the detector.

Next the detector is controlled (e.g., by controller 109 of FIG. 1 or image processing system 290 of FIG. 2) to successively address a plurality of sensing elements. The sensing elements may have a plurality of individually addressable sub-sensing elements. At step $1002, a first (or next) sensing element is addressed by, e.g., closing an associated element-bus switch to couple the sensing element to a signal readout path via a common signal bus. Other sensing elements on the same common signal bus or same dedicated signal readout path may be decoupled by opening their associated element-bus switches, so as to allow a signal received at a signal processing circuit to be uniquely associated with the sensing element that is being addressed.

At step S1003, a first (or next) sub-sensing element of the first (or next) sensing element is addressed. This is achieved by closing the sub-sensing element's associated sub-element switch to couple any signal from the sub-sensing element to the readout path via a sensing element node. In some embodiments, the sub-sensing element may comprise a group of sub-sensing elements as described with respect to FIG. 9 above. In this case the sub-element switch comprises a plurality of sub-element switches corresponding to sub-elements in the group. During the sub-sensing element addressing step S1003, other (non-grouped) sub-element switches may remain open so that any signal received at a signal processing circuit may be uniquely associated with the sub-sensing element (or group) that is being addressed. After the sub-sensing element is addressed, its sub-element switch may be opened to decouple the sub-sensing element from the readout path.

At step S1004 after the sub-sensing element has been addressed and any signal is received by a signal processing circuit on the readout path, it may be determined whether another sub-sensing element of the first (or next) sensing element remains to be addressed. If so, a next sub-sensing element may be selected at step S1005 and the addressing is repeated according to step S1003. If no sub-sensing elements of the sensing element remain to be addressed, the sensing element may be decoupled from the signal readout path by, e.g., opening its associated element-bus switch, and the process moves to step S1006.

At step S1006, it is determined whether another sensing element remains to be addressed. If so, a next sensing element may be selected at step S1007 and the addressing of all sub-sensing elements may be repeated for the next sensing according to steps 1002-1006. When no sensing elements remain to be addressed, the addressing process is completed. Information gained from the imaging process may be used to determine a high-resolution image of a beam spot for grouping boundary determination, SEM tuning/alignment, or used in other ways to influence imaging.

For example, the method may proceed to step S1010, wherein an adjustment may take place. The adjustment may include determining or adjusting a grouping of sensing elements, or sub-sensing elements. The adjustment may be performed by actuating (e.g., toggling) switches, such as switches between neighboring sensing elements, switches between neighboring sections, group switches, or sub-element switches. Examples of sub-element switches discussed above include, e.g., sub-element switches 522 as shown in FIG. 5C, sub-element switches 622 as shown in FIGS. 6A-6B, sub-element switches 722 as shown in FIG. 7. Connection status of switches may be changed between “on” and “off,” or another status (e.g., being connected to another branch of circuitry). The adjustment may be performed to more closely conform the beam spot boundary to the actual secondary beam spot formed on the detector. In some embodiments, the adjustment may include adjusting the trajectory of the primary beam or beamlets. The adjustment may be performed by adjusting a component of a column of a charged particle beam apparatus. For example, a deflector may be actuated to adjust beams passing therethrough. A Wein filter may be adjusted so that the trajectory of beams passing therethrough is influenced. In some embodiments, the adjustment may include adjusting the trajectory of secondary beams projected onto the detector. The adjustment may be performed by adjusting a component of a secondary imaging system, such as a zoom lens, anti-rotation lens, aberration compensation elements (e.g., stigmators), anti-scanning deflectors, or any other elements that may influence the properties of beams projected onto the detector. A feedback loop may be provided wherein information gained from the process of steps 1001 through 1007 is used to make an adjustment. The adjustment may include performing tuning or alignment of a charged particle beam system. The adjustment may enhance the collection efficiency of secondary particles, or reduce cross talk of neighboring secondary beam spots on the detector. Cross talk may be reduced by associating different groupings of sensing elements (including sub-sensing elements) with different beam spots. A beam spot identity (e.g., a first beam spot, second beam spot, . . . nth beam spot) may be associated with a group of sensing elements.

It should be understood that not all steps need necessarily be performed in the order described. For instance, the determination of which sensing elements and sub-sensing elements need not occur in real time, and the opening and closing of switches need not occur in the precise order given above. Any switching and determining operations may be used such that spatial information of sensing elements and sub-sensing elements may be obtained during a picture mode process.

A non-transitory computer-readable medium may be provided that stores instructions for a processor of a controller (e.g., controller 109 of FIG. 1 or image processing system 290 of FIG. 2) for detecting a charged-particle beam according to the exemplary flowchart of FIG. 10 above, consistent with embodiments in the present disclosure. For example, the instructions stored in the non-transitory computer-readable medium may be executed by the circuitry of the controller for performing method 1000 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Embodiments of the present disclosure may be further described by the following clauses:
1. A charged particle detector configured to operate in a picture mode or a beam mode, the charged particle detector comprising:
   a substrate comprising a first plurality of sub-sensing elements configured to convert a charged particle landing event into an electrical signal, each of the sub-sensing elements of the first plurality of sub-sensing elements being coupled to a switch on a first side of the sub-sensing element and being coupled to a first sensing element node of a first sensing element on a second side of the sub-sensing element,
   wherein each of the first plurality of sub-sensing elements is configured to generate a picture mode sub-pixel signal when the charged particle detector operates in the picture mode, each picture mode sub-pixel signal being separately accessible to a signal processing circuit of the charged particle detector in the picture mode, and
   wherein the first plurality of sub-sensing elements is configured to generate a first beam mode sensing element signal when the charged particle detector operates in the beam mode, the switches that are coupled to each of the sub-sensing elements in the first plurality of sub-sensing elements being closed in the beam mode, the first beam mode sensing element signal being accessible to the signal processing circuit of the charged particle detector in the beam mode.
2. The charged particle detector of clause 1, wherein the picture mode sub-pixel signal of each sub-sensing element is separately accessible to the signal processing circuit of the charged particle detector by separately addressing each switch for each sub-sensing element of the first plurality of sub-sensing elements in the picture mode.
3. The charged particle detector of clause 1, wherein the electrical signal of the picture mode sub-pixel signal or the beam mode sensing element signal is one of voltage, current, or charge.
4. The charged particle detector of clause 1, wherein the first plurality of sub-sensing elements comprises a plurality of PIN diodes.
5. The charged particle detector of clause 1, wherein each of the sub-sensing elements is coupled to the switch on a bias side of the sub-sensing elements.
6. The charged particle detector of clause 1, wherein each of the sub-sensing elements is coupled to the switch on a signal side of the sub-sensing elements.
7. The charged particle detector of clause 1, wherein the first side is a bias side.
8. The charged particle detector of clause 1, wherein the first side is a signal side.
9. The charged particle detector of clause 1, further comprising an element bus switch configured to connect the first sensing element to a signal bus.
10. The charged particle detector of clause 1, wherein a maximum resolution in the picture mode is higher than a maximum resolution in the beam mode.
11. The charged particle detector of clause 1, further comprising a controller configured to control the charged particle detector to:
   toggle a first switch coupled to a first sub-sensing element of the first plurality of sub-sensing elements to change a connection status of the first sub-sensing element and the sensing element node; and
   process, by the signal processing circuit, a first picture mode sub-pixel signal from the first sub-sensing element.
12. The charged particle detector of clause 11, wherein the controller is further configured to control the charged particle detector to:
   toggle the first switch coupled to the first sub-sensing element to change the connection status of the first sub-sensing element and the first sensing element node;
   toggle a second switch coupled to a second sub-sensing element of the first plurality of sub-sensing elements to change a connection status of the second sub-sensing element and the first sensing element node; and
   process, by the signal processing circuit, a second picture mode sub-pixel signal from the second sub-sensing element.
13. The charged particle detector of clause 12, wherein the controller is further configured to:
   determine a characteristic of a beam spot on the detector based on the first and second picture mode sub-pixel signals.
14. The charged particle detector of clause 13, wherein the characteristic includes one of spot shape, spot size, boundary determination, or spot identity.
15. The charged particle detector of clause 13, wherein the controller is further configured to:
   perform an adjustment based on the characteristic.
16. The charged particle detector of clause 12, wherein the controller is further configured to:
   determine a sensing element grouping for use in the beam mode based on the first and second picture mode sub-pixel signals.
17. The charged particle detector of clause 12, wherein the controller is further configured to:
   determine a parameter adjustment to a charged particle beam apparatus based on the first and second picture mode sub-pixel signals.
18. The charged particle detector of clause 17, wherein the parameter adjustment to the charged particle beam apparatus is a tuning adjustment of a scanning electron microscope.
19. The charged particle detector of clause 12, wherein the controller is further configured to:
   toggle the second switch coupled to the second sub-sensing element of the first plurality of sub-sensing elements to change a connection status of the second sub-sensing element and the first sensing element node;
   toggle a third switch coupled to a third sub-sensing element of a second plurality of sub-sensing elements to change a connection status of the third sub-sensing element and a second sensing element node of a second sensing element; and
   process, by the signal processing circuit, a third picture mode sub-pixel signal from the third sub-sensing element.
20. The charged particle detector of clause 11, wherein the controller is further configured to control the charged particle detector to:
   toggle a second switch coupled to a second sub-sensing element to change a connection status of the second sub-sensing element and the sensing element node, the first switch and the second switch having a same connection status during a same time period; and
   process, by the signal processing circuit, a combination of the first and second picture mode sub-pixel signals from the first and second sub-sensing elements as a picture mode sub-group pixel signal.
21. The charged particle detector of clause 1,
   the substrate further comprising a second plurality of sub-sensing elements, each of the sub-sensing elements of the second plurality being coupled to a switch on a first side and a second sensing element node of a second sensing element on a second side,
   wherein each of the second plurality of sub-sensing elements is configured to generate a picture mode sub-pixel signal in a picture mode, each picture mode sub-pixel signal being separately accessible to the signal processing circuit of the charged particle detector in the picture mode;
   wherein the second plurality of sub-sensing elements is configured to generate a second beam mode sensing element signal in a beam mode, the switches that are coupled to each of the sub-sensing elements in the second plurality of sub-sensing elements being closed in the beam mode, the second beam mode sensing element signal being accessible to the signal processing circuit of the charged particle detector in the beam mode.
22. The charged particle detector of clause 21, further comprising a group switch configured to connect the first sensing element to the second sensing element.
23. The charged particle detector of clause 21, further comprising a controller configured to:
   toggle each switch of the first plurality of sub-sensing elements to change a connection status between each sub-sensing element of the first plurality and the first sensing element node;
   toggle each switch of the second plurality of sub-sensing elements to change a connection status between each sub-sensing element of the second plurality and the second sensing element node; and
   process, by the signal processing circuit, a grouped beam mode sensing element signal comprising the first and second beam mode sensing element signals from the first and second sensing elements.
24. The charged particle detector of clause 21, further comprising a controller configured to:
   toggle each switch of the first plurality of sub-sensing elements to change a connection status between each sub-sensing element of the first plurality and the first sensing element node;
   toggle each switch of the second plurality of sub-sensing elements to change a connection status between each sub-sensing element of the second plurality from the second sensing element node; and
   process, by the signal processing circuit, a grouped beam mode sensing element signal comprising the first beam mode sensing element signal from the first sensing element.
25. The charged particle detector of clause 1, wherein the first plurality of sub-sensing elements is further configured to generate a beam mode partial sensing element signal when the charged particle detector operates in a second beam mode,
   a first subset of switches that are coupled to each of a first subset of sub-sensing elements in the first plurality of sub-sensing elements being closed in the second beam mode,
   a second subset of switches that are coupled to each of a second subset of sub-sensing elements in the first plurality of sub-sensing elements being open in the second beam mode,
   the beam mode partial sensing element signal being accessible to the signal processing circuit of the charged particle detector in the second beam mode.
26. An electron detector, comprising:
   a substrate comprising multiple PIN diodes, each of the diodes being coupled to a switch on one side and a beam pixel node on another side, each of the PIN diodes forming a picture mode pixel when in picture mode, the signal of each picture mode pixel being accessible to the detector when in picture mode; and
   multiple groups of PIN diodes, each of the PIN diodes of each group, when in beam mode, being part of a beam mode pixel comprising the group of PIN diodes, wherein the PIN diodes of each group are connected together via the switches on the beam pixel node side of each of the switches to enable the beam mode, the signal of the beam mode pixel being accessible to the detector when in beam mode.
27. A method of operating a charged particle beam detector configured to operate in a picture mode or a beam mode, the method comprising:
   addressing a first sensing element of a plurality of sensing elements of the charged particle beam detector by connecting the first sensing element to a signal readout path of the charged particle beam detector, the first sensing element comprising a first plurality of sub-sensing elements, each sub-sensing element being configured to convert a charged particle landing event into an electrical signal, each of the sub-sensing elements of the first plurality of sub-sensing elements being coupled to a switch on a first side of the sub-sensing element and being coupled to a first sensing element node of the first sensing element on a second side of the sub-sensing element;
   while the first sensing element is being addressed, individually addressing each sub-sensing element of first sensing element by successively toggling each switch coupled to each sub-sensing element on and off to individually connect each sub-sensing element of the first sensing element to the signal readout path; and
   performing an adjustment to a charged particle beam apparatus comprising the charged particle beam detector based on a signal obtained on the signal readout path from the first sensing element.
28. The method of clause 27, wherein:
   toggling each switch coupled to each sub-sensing element on allows charge generated in the sub-sensing element to flow to the signal readout path; and
   toggling each switch coupled to each sub-sensing element off prevents charge generated in the sub-sensing element from flowing to the signal readout path.
29. The method of clause 27, further comprising:
   disconnecting the first sensing element from the signal readout path;
   addressing a second sensing element of the plurality of sensing elements of the charged particle beam detector by connecting the second sensing element to the signal readout path of the charged particle beam apparatus, the second sensing element comprising a second plurality of sub-sensing elements, each sub-sensing element being configured to convert a charged particle landing event into an electrical signal, each of the sub-sensing elements of the second plurality of sub-sensing elements being coupled to a switch on a first side of the sub-sensing element and being coupled to a second sensing element node of the second sensing element on a second side of the sub-sensing element; and
   while the second sensing element is being addressed, individually addressing each sub-sensing element of second sensing element by successively toggling each switch coupled to each sub-sensing element on and off one at a time to individually connect each sub-sensing element of the second sensing element to the signal readout path;
   wherein performing the adjustment to the charged particle beam apparatus is further based on a signal obtained on the signal readout path from the second sensing element.
30. The method of clause 27, wherein the adjustment to the charged particle beam apparatus includes an adjustment to the charged particle beam detector.
31. The method of clause 30, wherein the adjustment to the charged particle beam detector comprises configuring or adjusting a grouping of sensing elements.
32. The method of clause 27, wherein the adjustment to the charged particle beam apparatus includes an adjustment to a component of the charged particle beam apparatus other than the charged particle beam detector.
33. A non-transitory computer-readable medium storing a set of instructions that are executable by at least one processor of a charged particle beam apparatus to cause the apparatus to perform a method comprising:
   addressing a first sensing element of a plurality of sensing elements of a charged particle beam detector by connecting the first sensing element to a signal readout path of the charged particle beam apparatus, the first sensing element comprising a first plurality of sub-sensing elements, each sub-sensing element being configured to convert a charged particle landing event into an electrical signal, each of the sub-sensing elements of the first plurality of sub-sensing elements being coupled to a switch on a first side of the sub-sensing element and being coupled to a first sensing element node of the first sensing element on a second side of the sub-sensing element;
   while the first sensing element is being addressed, individually addressing each sub-sensing element of first sensing element by successively toggling each switch coupled to each sub-sensing element on and off one at a time to individually connect each sub-sensing element of the first sensing element to the signal readout path; and
   performing an adjustment to the charged particle beam apparatus based on a signal obtained on the signal readout path from the first sensing element.
34. The non-transitory computer-readable medium of clause 33, wherein:
   toggling each switch coupled to each sub-sensing element on allows charge generated in each sub-sensing element to flow to the signal readout path; and
   toggling each switch coupled to each sub-sensing element off prevents charge generated in each sub-sensing element from flowing to the signal readout path.
35. The non-transitory computer-readable medium of clause 33, wherein the set of instructions that are executable by the at least one processor of the charged particle beam apparatus cause the apparatus to further perform:
   disconnecting the first sensing element from the signal readout path;
   addressing a second sensing element of the plurality of sensing elements of the charged particle beam detector by connecting the second sensing element to the signal readout path of the charged particle beam apparatus, the second sensing element comprising a second plurality of sub-sensing elements, each sub-sensing element being configured to convert a charged particle landing event into an electrical signal, each of the sub-sensing elements of the second plurality of sub-sensing elements being coupled to a switch on a first side of the sub-sensing element and being coupled to a second sensing element node of the second sensing element on a second side of the sub-sensing element; and
   while the second sub-sensing element is being addressed, individually addressing each sub-sensing element of second sensing element by successively toggling each switch coupled to each sub-sensing element on and off one at a time to individually connect each sub-sensing element of the second sensing element to the signal readout path;
   wherein performing the adjustment to the charged particle beam apparatus is further based on a signal obtained on the signal readout path from the second sensing element.
36. The non-transitory computer-readable medium of clause 33, wherein the adjustment to the charged particle beam apparatus includes an adjustment to the charged particle beam detector.
37. The non-transitory computer-readable medium of clause 36, wherein the adjustment to the charged particle beam detector comprises configuring or adjusting a grouping of sensing elements.
38. The non-transitory computer-readable medium of clause 33, wherein the adjustment to the charged particle beam apparatus includes an adjustment to a component of the charged particle beam apparatus other than the charged particle beam detector.

It will be appreciated that the embodiments of the present disclosure are not limited to the exact construction that has been described above and illustrated in the accompanying drawings and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A charged particle detector configured to operate in a picture mode or a beam mode, the charged particle detector comprising:
a substrate comprising a first plurality of sub-sensing elements configured to convert a charged particle landing event into an electrical signal, each of the sub-sensing elements of the first plurality of sub-sensing elements coupled to a switch on a first side of the sub-sensing element and coupled to a first sensing element node of a first sensing element on a second side of the sub-sensing element,
wherein each of the first plurality of sub-sensing elements is configured to generate a picture mode sub-pixel signal when the charged particle detector operates in the picture mode, each picture mode sub-pixel signal being separately accessible to a signal processing circuit of the charged particle detector in the picture mode, and
wherein the first plurality of sub-sensing elements is configured to generate a first beam mode sensing element signal when the charged particle detector operates in the beam mode, the switches being closed in the beam mode and the first beam mode sensing element signal being accessible to the signal processing circuit in the beam mode.

2. The charged particle detector of claim 1, wherein the picture mode sub-pixel signal of each sub-sensing element is separately accessible to the signal processing circuit by separately addressing each switch for each sub-sensing element of the first plurality of sub-sensing elements in the picture mode.

3. The charged particle detector of claim 1, wherein the electrical signal of the picture mode sub-pixel signal or the beam mode sensing element signal is one of voltage, current, or charge.

4. The charged particle detector of claim 1, further comprising an element bus switch configured to connect the first sensing element to a signal bus.

5. The charged particle detector of claim 1, further comprising a controller configured to control the charged particle detector to:
toggle a first switch coupled to a first sub-sensing element of the first plurality of sub-sensing elements to change a connection status of the first sub-sensing element and the first sensing element node; and
process, by the signal processing circuit, a first picture mode sub-pixel signal from the first sub-sensing element.

6. The charged particle detector of claim 5, wherein the controller is further configured to control the charged particle detector to:
toggle the first switch coupled to the first sub-sensing element to change the connection status of the first sub-sensing element and the first sensing element node;
toggle a second switch coupled to a second sub-sensing element of the first plurality of sub-sensing elements to change a connection status of the second sub-sensing element and the first sensing element node; and
process, by the signal processing circuit, a second picture mode sub-pixel signal from the second sub-sensing element.

7. The charged particle detector of claim 6, wherein the controller is further configured to determine a characteristic of a beam spot on the detector based on the first and second picture mode sub-pixel signals.

8. The charged particle detector of claim 7, wherein the characteristic includes one of spot shape, spot size, boundary determination, or spot identity.

9. The charged particle detector of claim 7, wherein the controller is further configured to perform an adjustment based on the characteristic.

10. The charged particle detector of claim 6, wherein the controller is further configured to determine a sensing element grouping for use in the beam mode based on the first and second picture mode sub-pixel signals.

11. The charged particle detector of claim 6, wherein the controller is further configured to determine a parameter adjustment to a charged particle beam apparatus based on the first and second picture mode sub-pixel signals.

12. The charged particle detector of claim 6, wherein the controller is further configured to:
toggle the second switch coupled to the second sub-sensing element of the first plurality of sub-sensing elements to change a connection status of the second sub-sensing element and the first sensing element node;
toggle a third switch coupled to a third sub-sensing element of a second plurality of sub-sensing elements to change a connection status of the third sub-sensing element and a second sensing element node of a second sensing element; and
process, by the signal processing circuit, a third picture mode sub-pixel signal from the third sub-sensing element.

13. The charged particle detector of claim 1, further comprising a second plurality of sub-sensing elements, each of the sub-sensing elements of the second plurality being coupled to a switch on a first side and a second sensing element node of a second sensing element on a second side,
wherein each of the second plurality of sub-sensing elements is configured to generate a picture mode sub-pixel signal in a picture mode, each picture mode sub-pixel signal being separately accessible to the signal processing circuit of the charged particle detector in the picture mode, and
wherein the second plurality of sub-sensing elements is configured to generate a second beam mode sensing element signal in a beam mode, the switches that are coupled to each of the sub-sensing elements in the second plurality of sub-sensing elements being closed in the beam mode, the second beam mode sensing element signal being accessible to the signal processing circuit of the charged particle detector in the beam mode.

14. The charged particle detector of claim 13, further comprising a controller configured to:
toggle each switch of the first plurality of sub-sensing elements to change a connection status between each sub-sensing element of the first plurality and the first sensing element node;
toggle each switch of the second plurality of sub-sensing elements to change a connection status between each sub-sensing element of the second plurality and the second sensing element node; and
process, by the signal processing circuit, a grouped beam mode sensing element signal comprising the first and second beam mode sensing element signals from the first and second sensing elements.

15. A non-transitory computer-readable medium storing a set of instructions that are executable by at least one processor of a charged particle beam apparatus to cause the apparatus to at least:
address a first sensing element of a plurality of sensing elements of a charged particle beam detector by connecting the first sensing element to a signal readout path of the charged particle beam apparatus, the first sensing element comprising a first plurality of sub-sensing elements, each sub-sensing element being configured to convert a charged particle landing event into an electrical signal, each of the sub-sensing elements of the first plurality of sub-sensing elements being coupled to a switch on a first side of the sub-sensing element and being coupled to a first sensing element node of the first sensing element on a second side of the sub-sensing element;
while the first sensing element is being addressed, individually address each sub-sensing element of the first sensing element by successively toggling each switch coupled to each sub-sensing element on and off one at a time to individually connect each sub-sensing element of the first sensing element to the signal readout path; and
perform an adjustment to the charged particle beam apparatus based on a signal obtained on the signal readout path from the first sensing element.

16. The medium of claim 15, wherein:
toggling of each switch coupled to each sub-sensing element on allows charge generated in each sub-sensing element to flow to the signal readout path; and
toggling of each switch coupled to each sub-sensing element off prevents charge generated in each sub-sensing element from flowing to the signal readout path.

17. The medium of claim 15, wherein the set of instructions that are executable by the at least one processor of the charged particle beam apparatus are further configured cause the apparatus to:
disconnect the first sensing element from the signal readout path;
address a second sensing element of the plurality of sensing elements of the charged particle beam detector by connecting the second sensing element to the signal readout path of the charged particle beam apparatus, the second sensing element comprising a second plurality of sub-sensing elements, each sub-sensing element being configured to convert a charged particle landing event into an electrical signal, each of the sub-sensing elements of the second plurality of sub-sensing elements being coupled to a switch on a first side of the sub-sensing element and being coupled to a second sensing element node of the second sensing element on a second side of the sub-sensing element; and
while the second sub-sensing element is being addressed, individually address each sub-sensing element of the second sensing element by successively toggling each switch coupled to each sub-sensing element of second sub-sensing element on and off one at a time to individually connect each sub-sensing element of the second sensing element to the signal readout path,
wherein the adjustment to the charged particle beam apparatus is further based on a signal obtained on the signal readout path from the second sensing element.

18. The medium of claim 15, wherein the adjustment to the charged particle beam apparatus includes an adjustment to the charged particle beam detector.

19. The medium of claim 18, wherein the adjustment to the charged particle beam detector comprises configuration or adjustment of a grouping of sensing elements.

20. An electron detector, comprising:
multiple PIN diodes, each of the diodes being coupled to a switch on one side and a beam pixel node on another side, each of the PIN diodes forming a picture mode pixel when in picture mode, the signal of each picture mode pixel being accessible to the detector when in picture mode; and
multiple groups of PIN diodes, each of the PIN diodes of each group, when in beam mode, being part of a beam mode pixel comprising the group of PIN diodes, wherein the PIN diodes of each group are connected together via the switches on the beam pixel node side of each of the switches to enable the beam mode, the signal of the beam mode pixel being accessible to the detector when in beam mode.
